(19) United States
(12) Patent Application Publication
(10) Pub. No.: US 2026/0121638 A1
(43) Pub. Date: Apr. 30, 2026

(54) EXTERNAL BUTTON SENSING DEVICE AND METHOD

(71) Applicant: NATIONAL TSING HUA UNIVERSITY, Hsinchu City (TW)

(72) Inventors: Hung-Wen CHEN, Hsinchu City (TW); Yi-Jiun SHEN, Hsinchu City (TW); Chen-Wei HU, Hsinchu City (TW)

(73) Assignee: NATIONAL TSING HUA UNIVERSITY, Hsinchu City (TW)

(21) Appl. No.: 19/085,000

(22) Filed: Mar. 20, 2025

(30) Foreign Application Priority Data
Oct. 30, 2024 (TW) 113141619

(51) Int. Cl. H03K 17/945; G01D 5/40

(52) U.S. Cl. CPC H03K 17/945; G01D 5/40

(57) ABSTRACT

A button sensing device includes: at least one sensor disposed at a first position relative to a button and including an inclined angle with the plane where the button is located; a system module electrically connected to the at least one sensor to receive sensing information from the at least one sensor and sending a control signal based on the sensing information; and a controller receiving the control signal and configured to trigger the button according to the control signal.

### TECHNICAL FIELD

The present disclosure relates to a touchless button sensing technology; specifically, the present disclosure relates to a touchless external button sensing device and a method thereof.

### BACKGROUND

The operation and contact with public equipment or open facilities in daily life will cause the spread of viruses and bacteria, exposing users to risks. For example, the apartments, the cooperation buildings, the hospitals and the clinics are more likely to be high-risk places because of their high turnover rate and the irregularity of people entering and exiting. The elevator panels, the vending machines and the door controlling systems in these places easily become breeding grounds of germs due to high frequency of use and the contact of users' fingers during operation.

In order to avoid direct contacts between the users and the buttons, infrared sensing technology, gesture recognition technology, and the like have been applied to the touchless button sensing. The button sensing system of gesture recognition utilizes a system that recognizes a specific gesture and controls the device according to the operations corresponding to the gestures. However, it is far different from the current button usage methods (such as touching and pressing) that the public is accustomed to, and the accuracy of image recognition is easily affected by different ambient light sources.

The existing infrared sensing button has an infrared sensor disposed within the button, which makes the infrared button only detect the area directly in front of the button, and it is limited by the layout of the button itself (for example, the button needs to accommodate indications such as numbers, door opening/closing patterns, and the like). The infrared sensor is usually disposed inside the relatively lower portion of the button, which does not conform to the operating habits of most users (for example, most users tend to apply force in the center of the button), therefore affecting the accuracy of the user's operation and the user experience. In addition, the aforementioned infrared sensing button needs to replace all the buttons on the panel, or even the entire panel during installation, thereby the cost and the time during installation are increased. Thus, there is a need for a touchless external button sensing technology that considers both the accuracy and the reduced installation cost.

### SUMMARY

An object of the present disclosure is to provide an external button sensing device and a method thereof, which can improve the accuracy of the touchless button sensing.

An object of the present disclosure is to provide an external button sensing device and a method thereof, which can be applied on the existing buttons by disposing additional sensor(s), so as to accomplish the purpose of touchless button sensing.

An object of the present disclosure is to provide an external button sensing device and a method thereof, which can provide a touchless button sensing conforming to the user intuition.

In an embodiment, a button sensing device includes: at least one sensor disposed at a first position relative to a button and including an inclination angle with the plane where the button is located; a system module electrically connected to the at least one sensor to receive sensing information from the at least one sensor and configured to send a control signal according to the sensing information; and a controller receiving the control signal and configured to trigger the button according to the control signal.

In another embodiment, a button sensing method includes: sensing a fan-shaped range in front of a button by at least one sensor, wherein the at least one sensor is disposed at a first position relative to the button and includes an inclination angle with the plane where the button is located; receiving sensing information from the at least one sensor by the system module and sending a control signal according to the sensing information; and receiving the control signal by a controller and triggering the button according to the control signal.

According to such a configuration, it can achieve the purpose of touchless button sensing without changing the user's operation habit, improving the accuracy of the sensor and reducing the incidence of inability to sense or false contact. In addition, using the external sensor can avoid replacing the entire panel or buttons, thereby saving the costs and improving the replacement efficiency.

### BRIEF DESCRIPTION OF THE DRAWINGS

FIG. 1A is a schematic view of an external button sensing device according to an embodiment of the disclosure.

FIG. 1B is a schematic block diagram of an external button sensing device according to an embodiment of the disclosure.

FIG. 2A is a schematic view of an external button sensing device according to another embodiment of the disclosure.

FIG. 2B is a front view of an external button sensing device according to another embodiment of the disclosure.

FIG. 3 is a front view of an external button sensing device according to yet another embodiment of the disclosure.

FIG. 4 is a flow chart of an external button sensing method according to an embodiment of the disclosure.

### DETAILED DESCRIPTION

An external button sensing device and a method thereof of the present disclosure are illustrated below by describing specific embodiments and accompanying drawings. People skilled in the art can understand the technical concepts and effects of the present disclosure through the subject matter. However, the subject matter disclosed below is not intended to limit the scope of the claims. Without departing from the spirit of the present disclosure, people skilled in the art may implement the subject matter by means of different embodiments in terms of structure and sequence of operation.

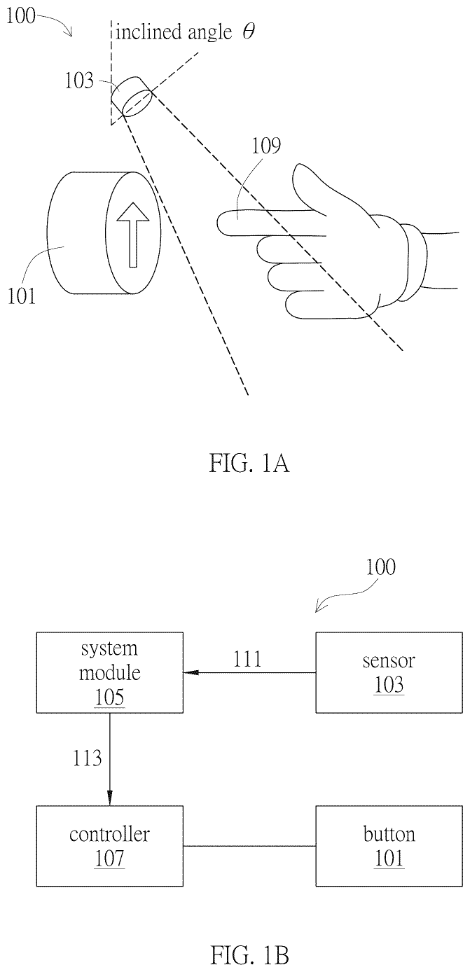

FIG. 1A and FIG. 1B illustrate an external button sensing device 100 according to an embodiment of the disclosure. The device 100 includes a sensor 103 disposed above a button 101, and the sensor 103 has an inclined angle θ with respect to a plane where the button 101 is located. The sensor 103 forms a fan-shaped sensing range (shown by the dotted lines in FIG. 1A) in front of the button 101. The sensing range will vary with the inclined angle θ, and the sensor 103 can be an infrared sensor and configured to sense whether an object (such as finger 109) approaches to the button 101. Referring to FIG. 1B, the sensor 103 can provide sensing information 111 corresponding to the button 101, wherein a system module 105 receives the sensing information 111, and sends a control signal 113 to a controller 107 in response to the indication of an object approaching to the button 101 according to the sensing information 111. The controller 107 is coupled to the button 101 and triggers the button 101 according to the control signal 113, so as to achieve the operations such as an elevator going up/down, opening/closing a door, and the like.

It should be noted that the sensor 103 can be any suitable sensor (such as an ultrasonic sensor, a depth sensor or a camera) other than an infrared sensor, so as to provide the sensing information such as distance range, angle, or depth, or the time-varying fluctuation of the sensing signal sensed and produced by the sensor 103. The system module 105 can send the control signal 113 according to different trigger conditions (for example, the finger 109 moves at a constant speed approaching the button 101, etc.), but not limited thereto. In addition, although the sensor 103 is shown to be disposed above the button 101 (e.g. at the upper side), the sensor 103 can be disposed at other positions (for example, left side, right side, lower side, upper left side, lower right side, etc.) with respect to the button 101 in other embodiments, and the disclosure is not limited thereto.

The system module 105 sends the control signal 113 to the controller 107 by, for example, triggering a relay (not shown), and the relay controls a dry contact of a circuit that the button 101 is connected to the controller 107. When the system module 105 triggers the relay, the relay will cause a short circuit to the dry contact in the circuit and simulate an effect of physically pressing the button 101, thus achieving an effect of sending the control signal 113 to the controller 107. Moreover, the system module 105 can be communicatively coupled (for example, via RS485 communication) to the controller 107, or sends the control signal 113 via any suitable method in other embodiments, and the disclosure is not limited thereto.

With such a configuration, the external sensor 103 can sense a space in front of the button 101. Compared with the configuration where the sensor is installed inside the bottom of the button, the sensing range of the external sensor 103 can be larger. In addition, by determining the position of the sensor 103 relative to the button 101 (e.g. above or below the button) and adjusting the inclined angle θ (for example, adjusted to 15°, 30° or 45°, etc.), the sensing range of the sensor 103 can be adjusted according to actual usage, so as to promote the accuracy of the touchless button sensing. For example, there may be a plurality of buttons on a same elevator panel; according to the layout of the elevator panel, each button is different in relative position (for example, a button with a door opening/closing pattern may be disposed at a relatively low position). Furthermore, the distance between the buttons may be different in different elevator panel layouts. Thus, the sensing accuracy of all buttons 101 on the same panel or different panels can be enhanced by adjusting the disposing position and the inclined angle θ of the sensor 103 for each button 101, thereby achieving the purpose of improving the accuracy of the button sensing device 100 and the user experience.

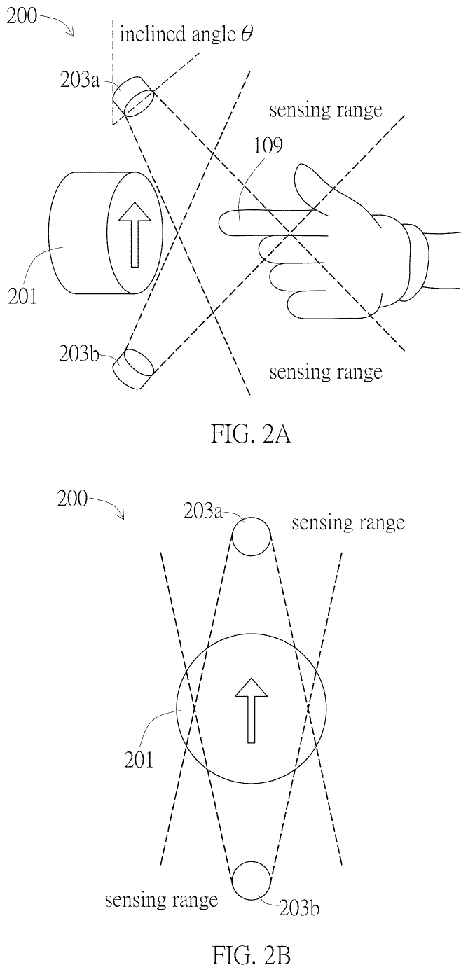

Referring to FIG. 2A and FIG. 2B, an external button sensing device 200 according to another embodiment of the disclosure is illustrated. In this embodiment, the device 200 includes a first sensor 203a and a second sensor 203b. The first sensor 203a and the second sensor 203b are respectively disposed at positions relative to a button 201 (e.g. above and below), and each has a respective inclined angle θ. The first sensor 203a and the second sensor 203b can have the same or different inclined angle θ, and the disclosure is not limited thereto. Referring to FIG. 2B, the first sensor 203a and the second sensor 203b can respectively form different but overlapping sensing regions (shown by the dotted lines in the drawing). The system module (such as the system module 105 shown in FIG. 1B) can send the control signal only when the sensing information of both of the first sensor 203a and the second sensor 203b satisfies the trigger conditions, so the possibility of accidental triggering can be decreased, and the purpose of increasing accuracy can be achieved.

It should be noted that the first sensor 203a and the second sensor 203b can be different types of sensors (for example, the infrared sensor and the ultrasonic sensor respectively) in different embodiments to provide different types of sensing information, and the disclosure is not limited thereto. In addition, the first sensor 203a and the second sensor 203b can have different triggering conditions. For example, a first triggering condition of the first sensor 203a can be that an object sensed; a second triggering condition of the second sensor 203b can be that an object approaching at a constant speed is sensed, and the like. The system module (such as the system module 105 shown in FIG. 1B) can send a control signal when one or both of the first triggering condition and the second triggering condition are satisfied, and the disclosure is not limited thereto.

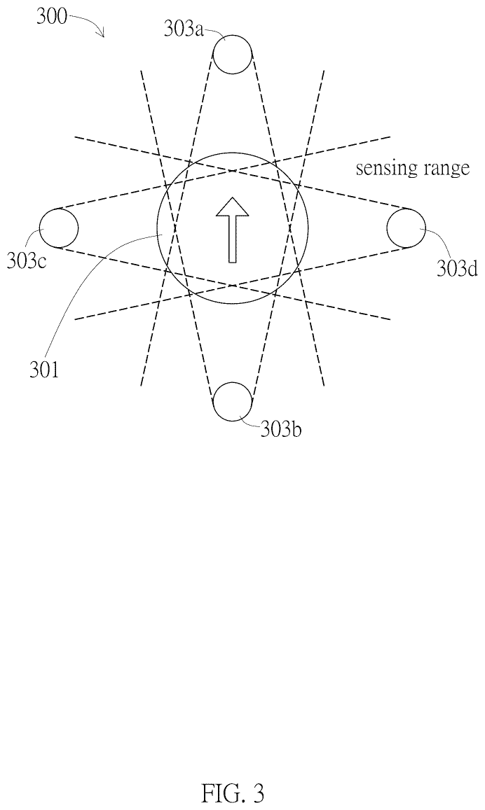

Referring to FIG. 3, an external button sensing device 300 according to yet another embodiment of the disclosure is illustrated. In this embodiment, the device 300 includes a first sensor 303a, a second sensor 303b, a third sensor 303c, and a fourth sensor 303d. Similar to the first sensor 203a and the second sensor 203b shown in FIG. 2A and FIG. 2B, the first sensor 303a, the second sensor 303b, the third sensor 303c and the fourth sensor 303d can respectively have an inclined angle θ and form overlapping sensing ranges (shown by the dotted lines in the drawing). The system module (such as the system module 105 shown in FIG. 1B) can send a control signal when the sensing information of all of the first sensor 303a, the second sensor 303b, the third sensor 303c and the fourth sensor 303d satisfies the triggering condition. It should be noted that the first sensor 303a, the second sensor 303b, the third sensor 303c and the fourth sensor 303d in this embodiment are respectively shown at the upper side, the lower side, the left side and the right side of the button 301; however, in a different embodiment, the sensors 303a to 303d can be disposed at any desired positions as appropriate (such as the upper right side, the lower right side, the upper left side, and the lower left side of the button 301), and the disclosure is not limited thereto. In addition, in this embodiment, the system module sends the control signal when the sensing information of all of the sensors 303a to 303d satisfies the triggering condition; however, in a different embodiment, the system module can send the control signal when the sensing information of one, two or three of the sensors 303a to 303d satisfies the triggering condition. Furthermore, similar to the first sensor 203a and the second sensor 203b shown in FIG. 2A and FIG. 2B, the sensors 303a to 303d can have different triggering conditions, and the disclosure will not elaborate again.

With such a configuration, the external button sensing device 300 can form a sensing range with high sensitivity. The button 301 can be smoothly and accurately triggered not matter the user approaches from what direction or operates by what posture, so as to achieve the purpose of improving the accuracy and the reliability of the external button sensing device 300. In addition, since the sensor (e.g. sensors 303a to 303d) is externally installed, the external button sensing device 300 can be easily applied to the conventional button (such as button 301), so the purposes of saving money and time costs can be achieved.

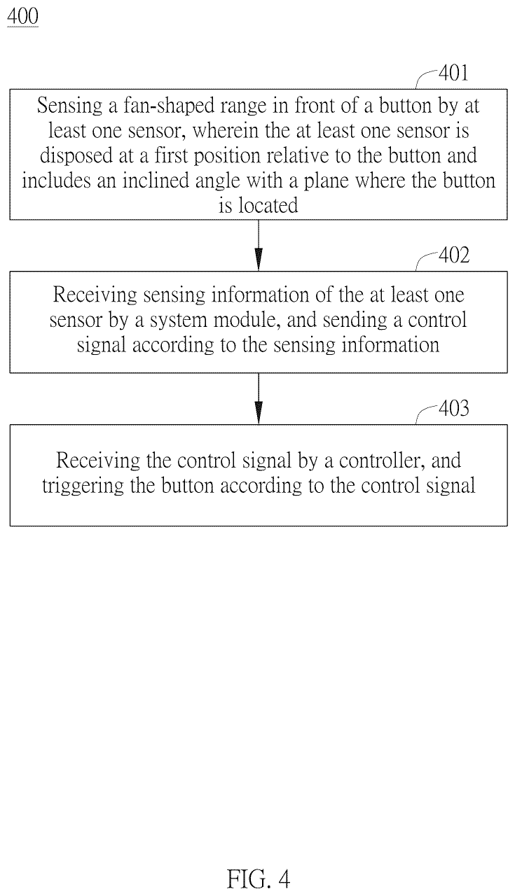

Referring to FIG. 4, an external button sensing method 400 according to a further another embodiment of the disclosure is illustrated. In this embodiment, the method 400 includes: sensing a fan-shaped range in front of a button by at least one sensor, wherein the at least one sensor is disposed at a first position relative to the button and includes an inclined angle with a plane where the button is located (401); receiving sensing information of the at least one sensor by a system module, and sending a control signal according to the sensing information (402); and receiving the control signal by a controller, and triggering the button according to the control signal (403). In this embodiment, the sensor can be any sensor described in the above embodiments (such as the sensor 103, the first sensor 203a or the first sensor 303a). Similar to the embodiments described above, the accuracy of the button sensing can be promoted by disposing the sensor relative to the button and including the inclined angle with the plane where the button is located. Users need not to relearn the triggering method of the button, so the purpose of improving the adaptability to uses can be achieved.

The above disclosure is only preferred embodiments of the present disclosure and is not intended to limit the claim scope of the disclosure. Furthermore, the order of the methods described herein is only for merely illustrative, and people skilled in the related art may modify the order of the steps under the equivalent concepts of the disclosure. In addition, unless there is a clear contradiction in the content of the description, the singular terms “a” and “the” used in the description also include the plural case, the terms “first” and “second” are intended to enable the people skilled in the related art to easily understand the concepts of the disclosure, and they are not intended to limit the property of the components of the disclosure. The shapes, positions and sizes of the elements, components and units of the accompanying drawings are intended to concisely and unambiguously show the technical content of the disclosure, and are not intended to limited the disclosure. At the same time, the well-known details or structures will be omitted from the drawings.

What is claimed is:

1. A button sensing device, comprising:
at least one sensor disposed at a first position relative to a button and including an inclined angle with a plane where the button is located;
a system module electrically connected to the at least one sensor to receive sensing information of the at least one sensor, and configured to send a control signal according to the sensing information; and
a controller receiving the control signal and configured to trigger the button according to the control signal.

2. The device according to claim 1, wherein the sensing information includes a distance range, an angle, a depth or a time-varying fluctuation of a sensing signal sensed and produced by the at least one sensor.

3. The device according to claim 1, wherein the system module sending the control signal includes sending the control signal in response to an indication of a triggering condition being satisfied according to the sensing information.

4. The device according to claim 1, wherein the first position includes one of above, below, left side or right side of the button.

5. The device according to claim 1, wherein the at least on sensor further includes a first sensor and a second sensor, the first sensor is disposed at the first position, the second sensor is disposed at a second position relative to the button, and the first sensor and the second sensor have the same inclined angle or different inclined angles.

6. The device according to claim 5, wherein the sensing information of the first sensor and the sensing information of the second sensor independently includes a distance range, an angle, a depth or a time-varying fluctuation of a sensing signal sensed and produced by at least one of the first sensor and the second sensor.

7. The device according to claim 5, wherein the system module sending the control signal includes sending the control signal in response to an indication of a first triggering condition being satisfied according to the sensing information of the first sensor and/or an indication of a second triggering condition being satisfied according to the sensing information of the second sensor.

8. The device according to claim 1, wherein the at least one sensor includes a first sensor, a second sensor, a third sensor and a fourth sensor; the first sensor is disposed at the first position; the second sensor, the third sensor and the fourth sensor are respectively disposed at a second position, a third position and a fourth position, and the first sensor, the second sensor, the third sensor and the fourth sensor have the same inclined angle or different inclined angles.

9. The device according to claim 8, wherein the sensing information of the first sensor, the second sensor, the third sensor and the fourth sensor independently includes a distance range, an angle, a depth or a time-varying fluctuation of a sensing signal sensed and produced by at least one of the first sensor, the second sensor, the third sensor and the fourth sensor.

10. The device according to claim 8, wherein the system module sending the control signal includes sending the control signal in response to an indication of a triggering condition being satisfied according to the sensing information of at least one of the first sensor, the second sensor, the third sensor and the fourth sensor.

11. A button triggering method, comprising:
sensing a fan-shaped region in front of a button by at least one sensor, wherein the at least one sensor is disposed at a first position relative to the button, and includes an inclined angle with a plane where the button is located;
receiving sensing information of the at least one sensor by a system module, and sending a control signal according to the sensing information; and
receiving the control signal by a controller, and triggering the button according to the control signal.

12. The method according to claim 11, wherein the sensing information includes a distance range, an angle, a depth or a time-varying fluctuation of a sensing signal sensed and produced by the at least one sensor.

13. The method according to claim 11, wherein the system module sending the control signal includes sending the control signal in response to an indication of a triggering condition being satisfied according to the sensing information.

14. The method according to claim 11, wherein the first position includes one of above, below, left side or right side of the button.

15. The method according to claim 11, wherein the at least on sensor further includes a first sensor and a second sensor, the first sensor is disposed at the first position, the second sensor is disposed at a second position relative to the button, and the first sensor and the second sensor have the same inclined angle or different inclined angles.

16. The method according to claim 15, wherein the sensing information of the first sensor and the sensing information of the second sensor independently include a distance range, an angle, a depth or a time-varying fluctuation of a sensing signal sensed and produced by at least one of the first sensor and the second sensor.

17. The method according to claim 15, wherein the system module sending the control signal includes sending the control signal in response to an indication of a first triggering condition being satisfied according to the sensing information of the first sensor and/or an indication of a second triggering condition being satisfied according to the sensing information of the second sensor.

18. The method according to claim 11, wherein the at least one sensor includes a first sensor, a second sensor, a third sensor and a fourth sensor; the first sensor is disposed at the first position; the second sensor, the third sensor and the fourth sensor are respectively disposed at a second position, a third position and a fourth position, and the first sensor, the second sensor, the third sensor and the fourth sensor include the same inclined angle or different inclined angles.

19. The method according to claim 18, wherein the sensing information of the first sensor, the second sensor, the third sensor and the fourth sensor independently include a distance range, an angle, a depth or a time-varying fluctuation of a sensing signal sensed and produced by at least one of the first sensor, the second sensor, the third sensor and the fourth sensor.

20. The method according to claim 18, wherein the system module sending the control signal includes that sending the control signal in response to an indication of a triggering condition being satisfied according to the sensing information of at least one of the first sensor, the second sensor, the third sensor and the fourth sensor.
